(19) United States
(12) Patent Application Publication
(10) Pub. No.: US 2024/0314984 A1
(43) Pub. Date: Sep. 19, 2024

(54) POWER SUPPLY WITH EXTERNALLY MOUNTED FAN DEVICE

(71) Applicant: EVGA CORPORATION, New Taipei City (TW)

(72) Inventor: Tai-Sheng Han, New Taipei City (TW)

(21) Appl. No.: 18/120,425

(22) Filed: Mar. 13, 2023

(51) Int. Cl. H05K 7/20

(52) U.S. Cl. CPC H05K 7/20909; H05K 7/20172

(57) ABSTRACT

The present invention includes a power supply unit composed of a casing and a current conversion unit, a slotted wall, a fan device composed of a fan and a fan support, a chamber, and a slant rim. The fan device is detachably joined to the casing for convenient maintenance and replacement. The fan is housed in the fully open chamber for reduced impedance and noise. The slant rim tapers toward the chamber and facilitates airflow for enhanced heat dissipation performance.

### BACKGROUND OF THE INVENTION

### (a) Technical Field of the Invention

The present invention is generally related to power supplies, and more particular to a power supply integrated with an externally mounted fan device.

### (b) Description of the Prior Art

Computer power supplies are equipped with one or more fans for heat dissipation. A common problem to computer power supplies is dust accumulation compromising the effect of heat dissipation and causing the fans, the power supply, and the computer to malfunction. These fans are usually internally configured and, as such, they are not convenient to clean and maintain. Due to safety concern, the users are advised not to replace the fans by themselves. These internal fans are also of specific specifications, and are not easy to obtain.

R.O.C Taiwan Patent No. M247926 teaches a power supply with externally mounted fan module. The power supply has a casing with fastener elements and the fan module may be detachably mounted to the casing. As such, the fan module can be hot-swapped and maintained. This teaching still has the following shortcomings.

First, the fan module is mounted to a porous wall of the casing. Noises in addition to those of the fan module itself are produced as air flowing through the porous wall. The porous wall also makes the air flow sluggish, increases the impedance of the fan module, and causes inferior energy conversion efficiency.

Second, if the porous wall allows unidirectional air flow, heat may be accumulated around the wall. If the porous wall allows multidirectional air flow, the heat dissipation may be improved yet the fan module would suffer even greater impedance.

### SUMMARY OF THE INVENTION

A major objective of the present invention is to detachably mount a fan device externally to a power supply unit through fastener elements so that the fan device is convenient to detach, clean, and maintain.

Another major objective of the present invention is to house a fan of the fan device inside a fully-open chamber to effectively reduce fan device's impedance and noise.

A further major objective of the present invention is to have an airflow guiding design to prevent heat accumulation around the fan device for enhanced heat dissipation.

To achieve the above objectives, the present invention mainly includes a power supply unit composed of a casing and a current conversion unit, a slotted wall, a fan device composed of a fan and a fan support, a chamber, and a slant rim. The current conversion unit is housed in the casing. The slotted wall forms the top side of the casing. The fan device is detachably joined to the slotted wall of the casing through fastener elements. The fan support is configured on the casing and surrounds the fan. The chamber is provided on the fan support where the fan is embedded. The chamber has a greater diameter than that of the fan. The slant rim is provided on the fan support around the chamber and tapers towards the chamber.

According to the present invention, the fan device is not configured internally inside the power supply unit, but externally mounted to the casing through fastener elements. Therefore, for cleaning, maintenance, and replacement of the fan device, there is no need to disassemble the casing and, as such, the high-voltage current conversion unit remains sealed inside the casing. In addition, the fan is housed in the fully open chamber for reduced impedance and noise. The fan support protects the fan and the slant rim, as it tapers toward the chamber, facilitates airflow for enhanced heat dissipation performance.

As described above, the present invention obviates the shortcomings of the prior art such as inconvenient maintenance and replacement, high fan device impedance, loud noise, and heat accumulation

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective diagram showing a power supply with externally mounted fan device according to a first embodiment of the present invention.

FIG. 2 is a perspective break-down diagram showing the power supply of FIG. 1.

FIG. 3 is a schematic sectional diagram showing air flow of the power supply of FIG. 1.

FIG. 4 is a perspective diagram showing a power supply with externally mounted fan device according to a second embodiment of the present invention.

FIG. 5 is a schematic sectional diagram showing the integration of a fan device and a power supply unit of the power supply of FIG. 4.

FIG. 6 is a perspective diagram showing the assembly of a power supply with externally mounted fan device according to a third embodiment.

FIG. 7 is another perspective diagram showing the assembly of the power supply of FIG. 6.

FIG. 8 is a perspective diagram showing the assembly of a power supply with externally mounted fan device according to a fourth embodiment.

FIG. 9 is another perspective diagram showing the assembly of the power supply of FIG. 8.

FIG. 10 is another perspective diagram showing the assembly of the power supply of FIG. 8.

FIG. 11 is a perspective diagram showing the power supply of FIG. 8 with its lighting module turned on.

FIG. 12 is a perspective diagram showing the configuration of a fan on a power supply according to a fifth embodiment of the present invention.

FIG. 13 is a perspective break-down diagram showing the power supply of FIG. 12.

FIG. 14 is a perspective diagram showing the configuration of a fan on a power supply according to a sixth embodiment of the present invention.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

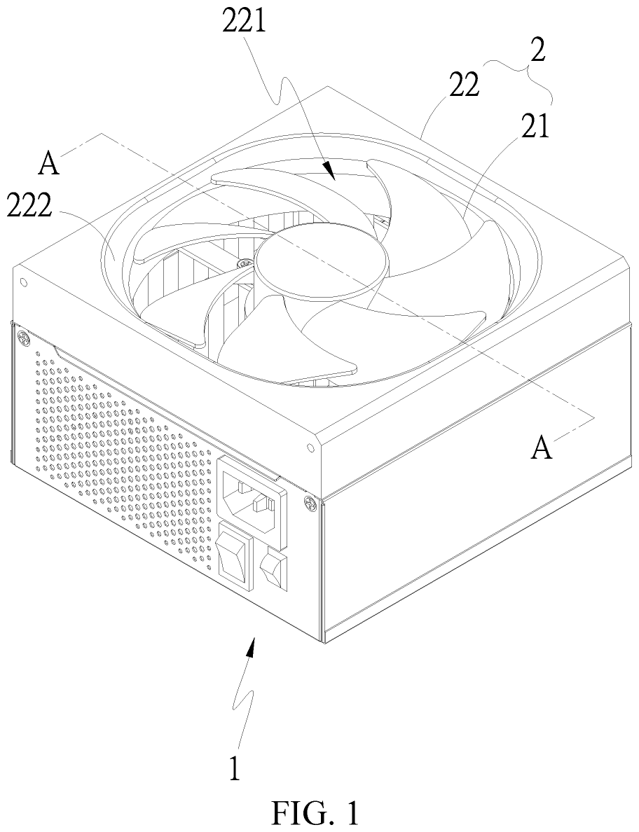

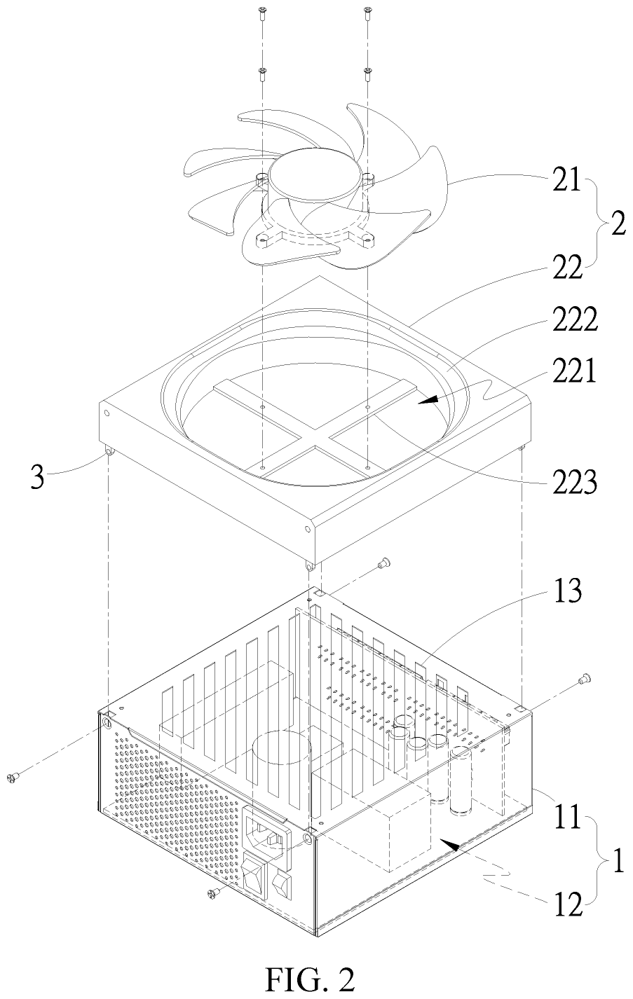

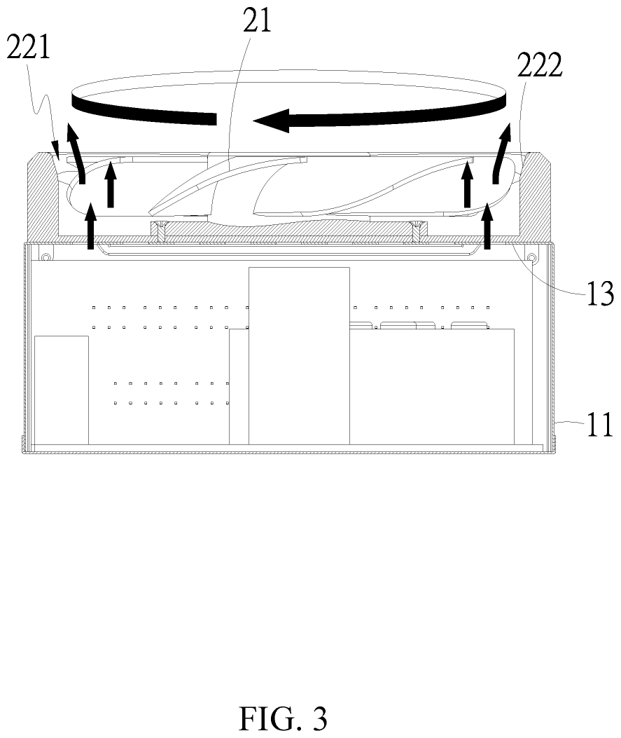

As shown in FIGS. 1 to 3, a first embodiment of the present invention includes:

a power supply unit (PSU) 1 including a casing 11 and a current conversion unit 12 inside the casing 11;

a slotted wall 13 forming a top side of the casing 11;

a fan device 2 externally joined to the slotted wall 13 of the casing 11 through at least a fastener element 3, where the fan device 2 includes a fan 21 and a fan support 22 in which the fan 21 is embedded;

a chamber 221 on a top side of the fan support 22 away from the slotted wall 13, where the chamber 221 has a greater diameter than that of the fan 21; and

a slant rim 222 on the top side of the fan support 22 around the chamber 221 where the slant rim 222 tapers towards the chamber 221.

The fan device 2 and the PSU 1 are separate objects. In the present embodiment, to assemble the fan device 2, the fan 21 is fixed to a cross-shaped stand 223 at a bottom side of the chamber 221 so that the fan 21 is embedded in the fan support 22 and the fan 21's rotation would not be interfered. In the present embodiment, the fastener elements 3 are pegs extended from the four comers of the fan support 22's bottom side, through which the fan device 2 is fixed to the casing 11. However, the present invention is not limited as such. The fastener elements 3 may provide connection through screwing, locking, or plugging. In the above assembly process, safety is maintained as the high-voltage current conversion unit 12 remains sealed inside the PSU 1. On the other hand, the fan device 2 may be conveniently removed by releasing the connection of the fastener elements 3 to the PSU 1. The fan 21, then, may be cleaned, maintained, or replaced. Depending on user's demand for silence, balance, or performance, a different type of the fan 21 can be adopted.

As the chamber 221 has a completely open top side, air flow produced by the fan 21 is not hindered, thereby effectively reducing the impedance and noise, and enhancing the performance of the fan device. The fan support 22, in addition to provide protection to the fan 21, has a guiding effect to the air flow by the taper shape of its slant rim 222, enhancing the heat dissipation performance.

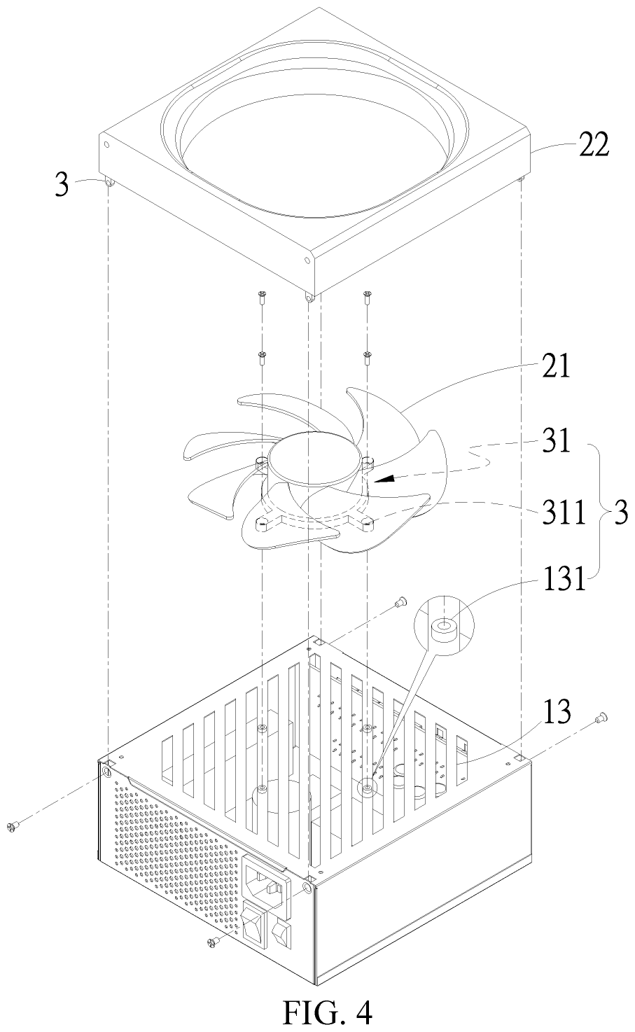

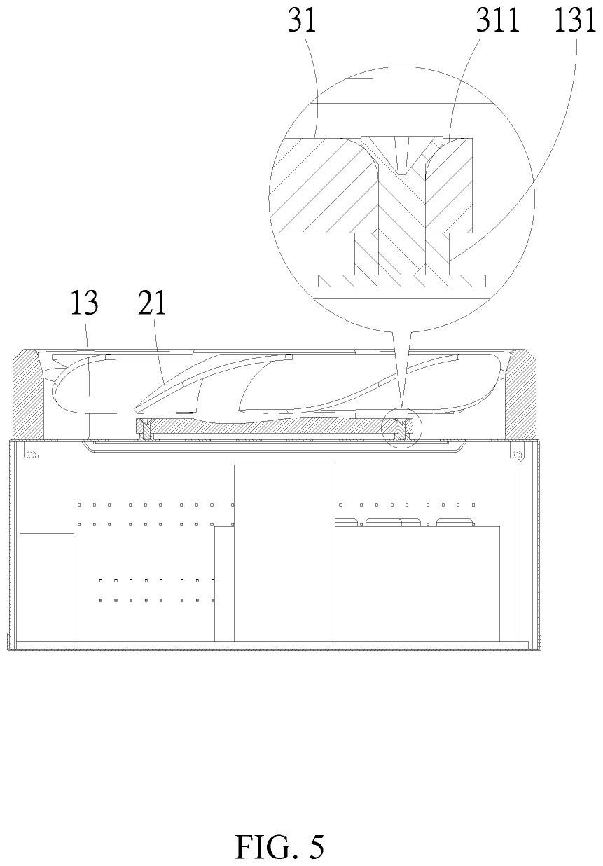

As shown in FIGS. 4 and 5, a second embodiment differs from the previous embodiment in that the fastener elements 3, other than those on the fan support 22, further include a number of sockets 131 on the slotted wall 13 and a same number of corresponding through holes 311 on a fan base 31 beneath the fan 21. By applying screws through the pairs of threaded sockets 131 and through holes 311, the fan 21 is fixed not to the fan support 22 but directly to the slotted wall 13. The fan base 31 raises the fan 21 above the slotted wall 13 for a distance so that the rotation of the fan 21 does not contact with the slotted wall 13. This design also reduces the impedance caused by the slotted wall 13. In the present embodiment, the sockets 131 are extended from the slotted wall 13 so that the screws do not penetrate the slotted wall 13. The extended sockets 131 further enlarge the gap between the fan 21 and the slotted wall 13.

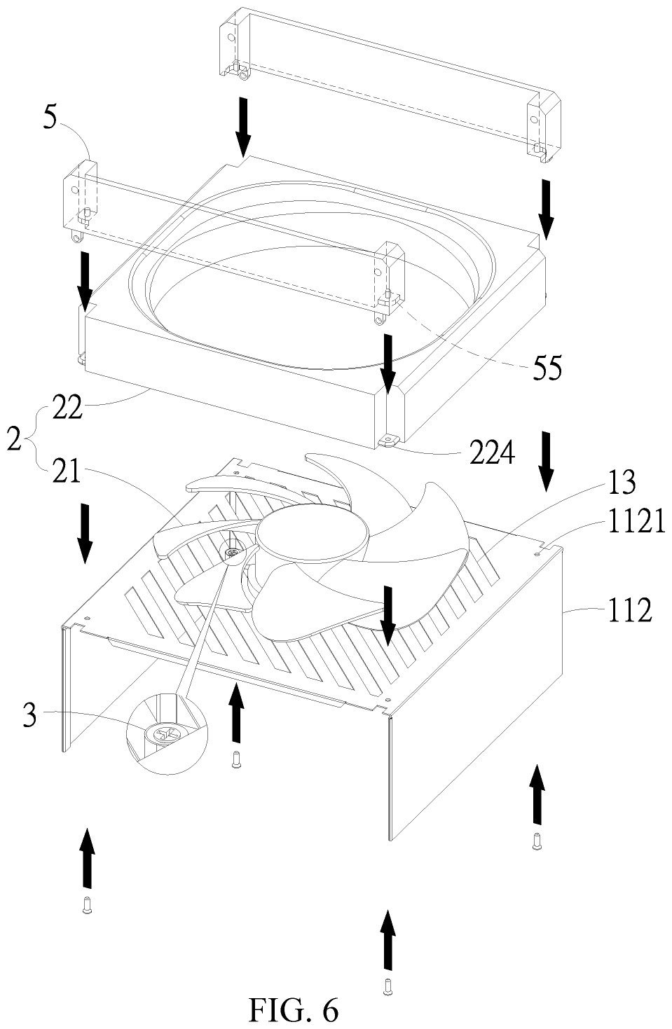

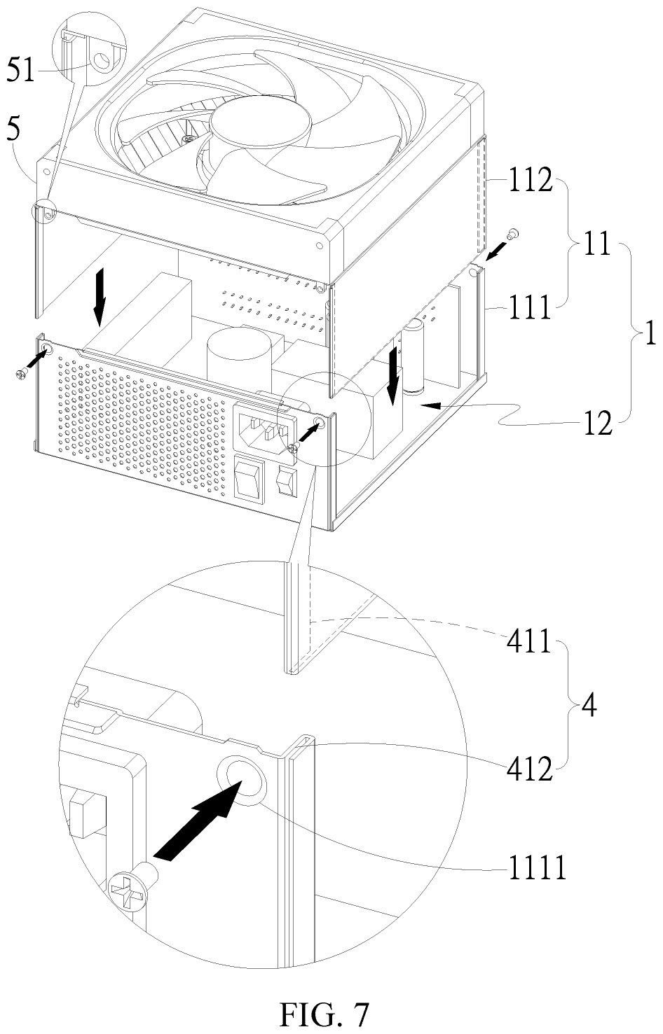

As shown in FIGS. 6 and 7, a third embodiment of the present invention differs from the previous embodiment in the following. The casing 11 includes a bottom piece 111 on which the current conversion unit 12 is configured, a top piece 112 correspondingly joining the bottom piece 111, and limiting elements 4 for joining the bottom piece 111 and the top piece 112. The slotted wall 13 is formed on the top piece 112. In addition, the fan support 22 is laterally sandwiched between a pair of fastener pieces 5. The fastener pieces 5 replace the pegs of the previous embodiments, and respectively have first locking elements 51 extended downward for joining with the bottom piece 111.

The PSU 1 of the present embodiment includes a U-shaped bottom piece 111 and an inverted-U-shaped top piece 112. In assembly, the fan 21 can be first fixed to the slotted wall 13 of the top piece 112. The fan support 22 is then fixed to the top piece 112. As the PSU 1 involves this two-piece structure, to reduce the vibration from the fan device 2, the fastener pieces 5 are additionally applied. In the present embodiment, there are two fastener pieces 5. During assembly, four third locking elements 224 at the comers of the fan support 22 are aligned with second locking holes 1121 of the top piece 112, and screws are applied downward through second locking elements 55 of the fastener pieces 5, the first locking elements 224, and the second locking holes 1121. Then, the first locking elements 51 of the fastener pieces 5 are aligned and joined to first locking holes 1111 of the bottom piece 111. As such, the fan device 2 is simultaneously fixed to the top piece 112 and the bottom piece 111 of the PSU 1 to achieve reduced vibration. Finally, through the engagement of the limiting elements 4, the top piece 112 and the bottom piece 111 are joined. In the present embodiment, each limiting element 4 includes a first limiting trough 411 along an edge of the top piece 112 and a second limiting trough 412 along an edge of the bottom piece 111. The first limiting troughs 411 and the second limiting troughs 412 have interlocking cross-sections so that the top piece 111 is slid downward to couple with the bottom piece 111.

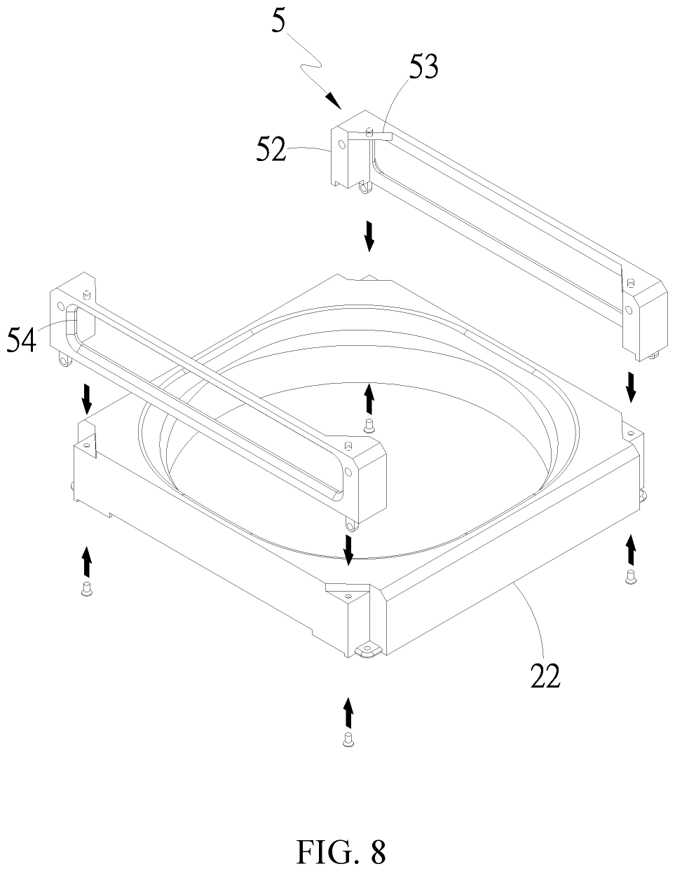

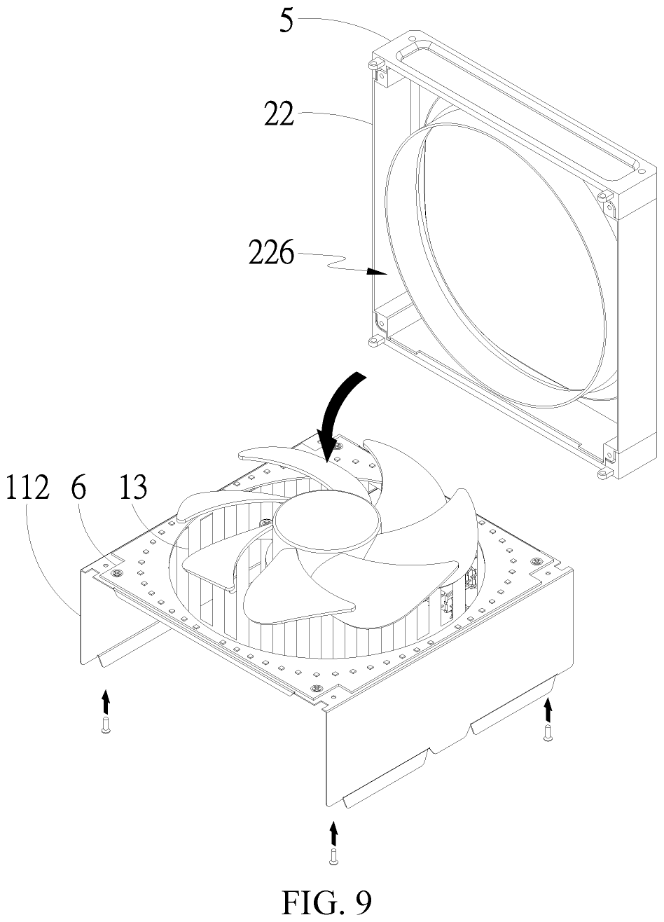

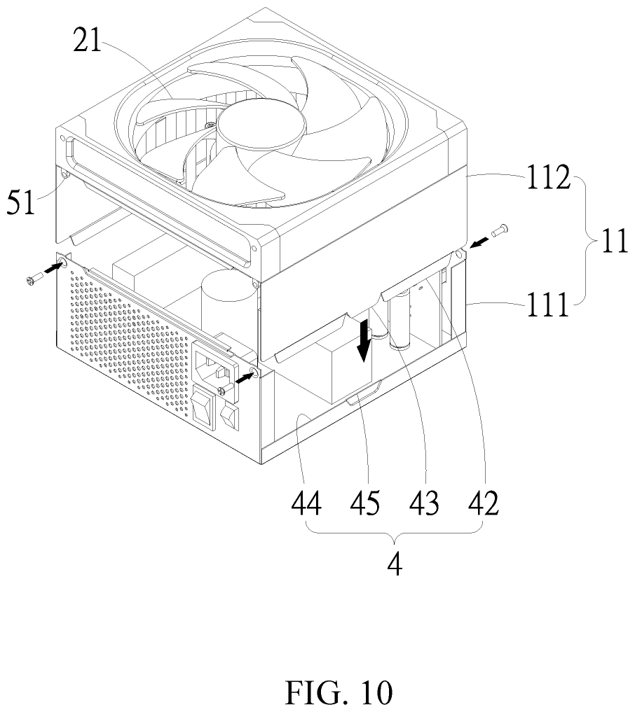

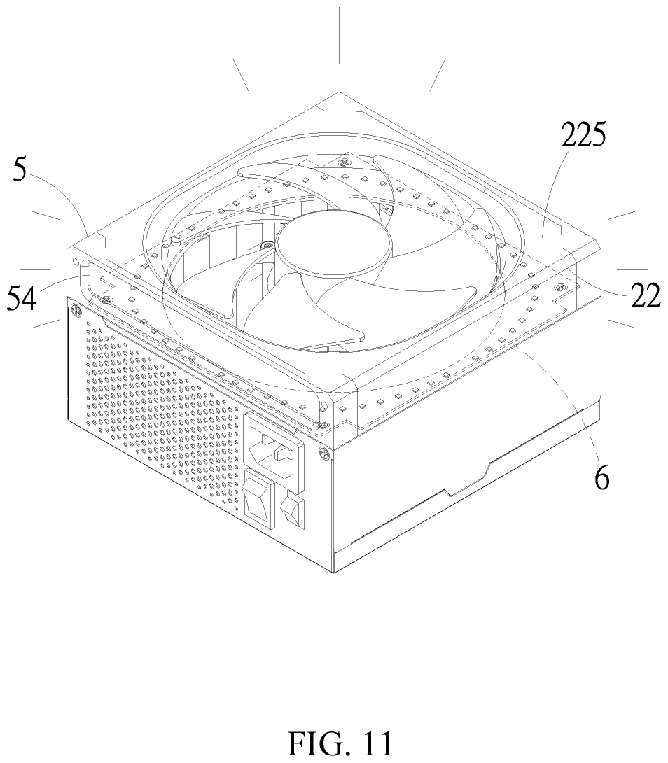

As shown in FIGS. 8 to 11, a fourth embodiment of the present invention differs from the previous embodiments in that a lighting module 6 is further provided between the casing 11 and the fan support 22. The top side of the fan support 22 has a translucent section 225. The fan support 22 also has an inward concave section 226 at the bottom to give way to the lighting module 6. Each fastener piece 5 has an arm segment 52 respectively at both ends, a hollowed-out segment 54 between the arm segments 52, and a cap segment 53 between an arm segment 52 and the hollowed-out segment 54. This design is to further enhance the fastener pieces 5's strength and anti-vibration performance. The arm segments 52 increase the tightness between the fastener pieces 5 and the fan support 22. The cap segments 53 further provides downward press against the fan support 22 so that the fan support 22 is closely attached to the top piece 112. Therefore, the fan support 22, the fastener pieces 5, and the top piece 112 are tightly joined together. Further by the first locking elements 51's locking to the bottom piece 111, the noise from the fan 21 and its vibration to the casing 11 are both reduced to the minimum level.

The lighting module 6 is locked to the top piece 112 around the top side of the slotted wall 13, and is entirely covered by the concave section 226 of the fan support 22. The translucent section 225 is made of a semi-transparent, transparent, or light-guiding material and light from the lighting module 6 may be projected outside the fan support 22. The lighting module 6 includes multiple LEDs of different colors, providing appealing visual effect. The hollowed out segments 54 on the fastener pieces 5 allow the light from the lighting module 6 to pass through, and also reduce the material cost.

In the present embodiment, each limiting element 4 includes inner flanks 42 and outer flanks 43 along a bottom edge of the top piece 112, and a corresponding upward flank 44 on the bottom piece 111 and a notch 45 on the upward flank 44. In assembly, the notch 45 receives the outer flank 43 and the inner flanks 42 press against the upward flank 44 from inside of the upward flank 44. In other words, the limiting elements 4 join the bottom piece 111 and the top piece 112 through the clamping by the flanks.

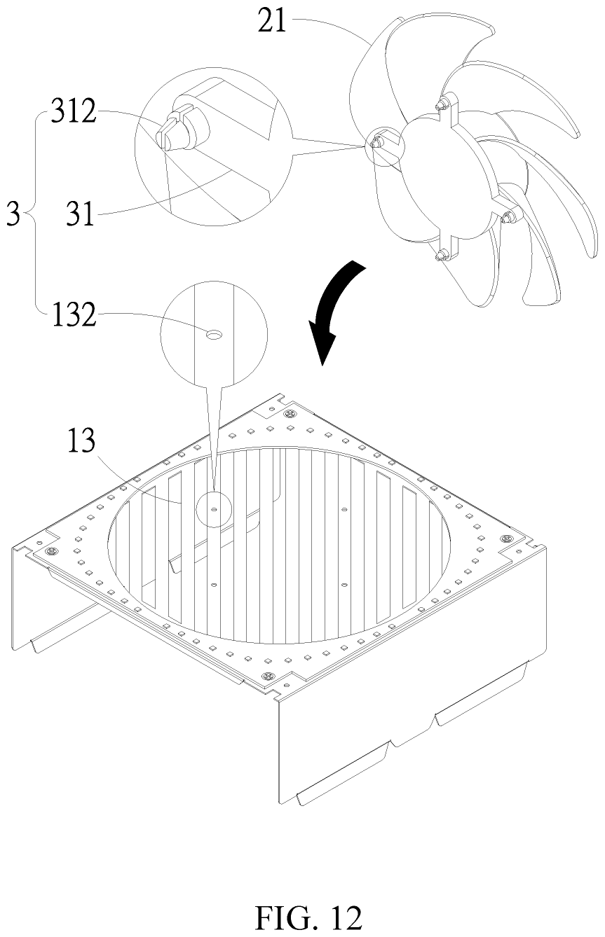

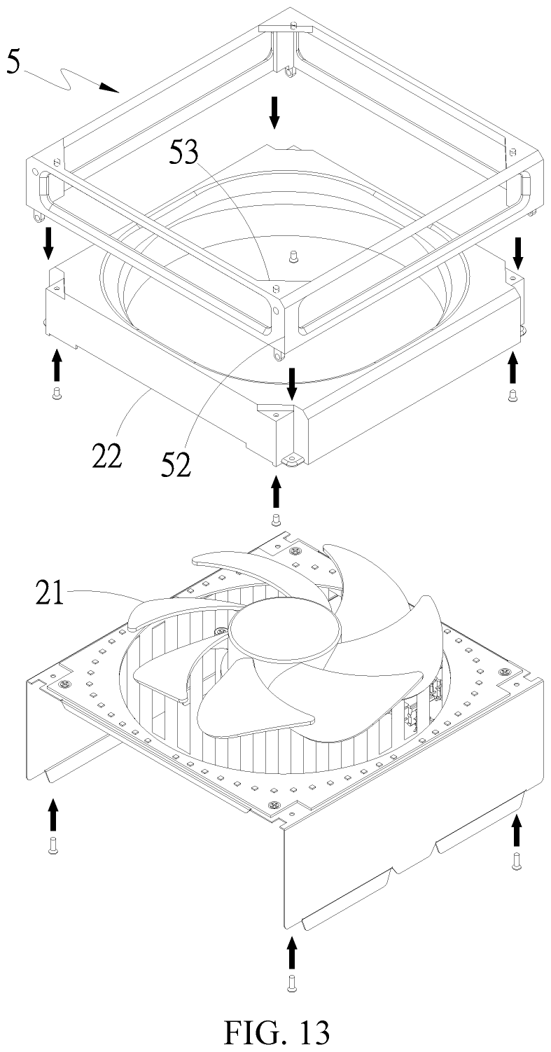

As shown in FIGS. 12 and 13, a fifth embodiment of the present invention differs from the previous embodiments in that the fastener elements 3 include a number of positioning holes 132 on the slotted wall 13 and a number of positioning pins 312 beneath the fan base 31. Each positioning pin 312 has an arrow-shaped tip. By aligning and pressing the positioning pins 312 against the positioning holes 132, the positioning pins 312 would plug into the positioning holes 132, achieving the fixation of the fan 21 without using tools. In addition, the present embodiment has a single fastener piece 5 integrally formed as a rectangular frame. The single fastener piece 5 includes similar cap segments 53 and arm segments 52. The cap segments 63 still press downward against the fan support 22. The arm segments 52 still adjoin the four corners of the fan support 22. However, due to that the fastener piece 5 is integrally formed, the fastener piece 5 would be more robust, enhancing its protection to the fan 21 and the fan support 22.

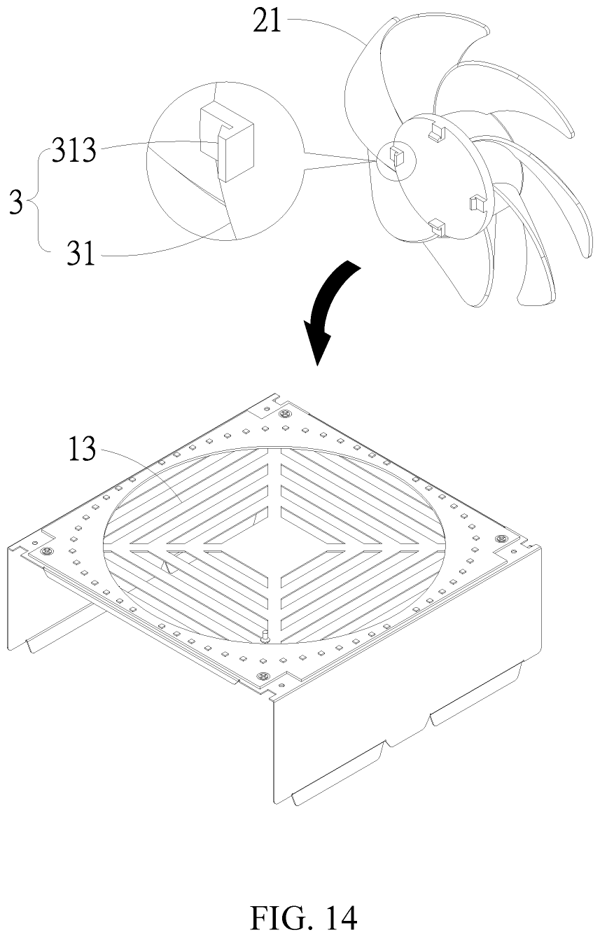

As shown in FIG. 14, a sixth embodiment of the present invention differs from the previous embodiments in that the fastener elements 3 include a number of hooks 313 beneath the fan base 31 and the slotted wall 13 has the slots arranged rectangularly. In assembly, the hooks 313 run through the slots and engage the slotted wall 13 at multiple locations. The fixation of the fan 21, therefore, can be conducted without using tools, and the fan 21 is prevented from displacement on slotted wall 13.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the claims of the present invention.

I claim:

1. A power supply with externally mounted fan device, comprising:
a power supply unit (PSU) comprising a casing and a current conversion unit inside the casing;
a slotted wall forming a top side of the casing;
a fan device externally joined to the top side of the slotted wall of the casing through a plurality of fastener elements, where the fan device comprises a fan and a fan support in which the fan is embedded;
a chamber on a top side of the fan support away from the slotted wall, where the chamber has a greater diameter than that of the fan and the fan is accommodated in the chamber, and
a slant rim on the top side of the fan support around the chamber where the slant rim tapers towards the chamber.

2. The power supply according to claim 1, further comprising a lighting module between the casing and the fan support.

3. The power supply according to claim 2, wherein the fan support comprises a translucent section and a concave section to give way to the lighting module.

4. The power supply according to claim 1, wherein the casing comprises a bottom piece on which the current conversion unit is configured, a top piece correspondingly joining the bottom piece, and a plurality of limiting elements for joining the bottom piece and the top piece; and the slotted wall is formed on the top piece.

5. The power supply according to claim 1, wherein a bottom piece on which the current conversion unit is configured, and a top piece correspondingly joining the bottom piece; the fan support is configured on the top piece; the fan support comprises at least a fastener piece; and the at least one fastener piece has a plurality of first locking elements extended downward for joining with the bottom piece.

6. The power supply according to claim 5, wherein the at least one fastener piece comprises an arm segment respectively at both ends, a hollowed-out segment between the arm segments, and a cap segment between an arm segment and the hollowed out segment.

7. The power supply according to claim 1, wherein fastener elements comprise a fan base beneath the fan; and the fastener elements provide connection through screwing, locking, or plugging.

8. The power supply according to claim 7, wherein the fastener elements further comprise through holes on the fan base and a plurality of sockets on the slotted wall corresponding to the through holes.

9. The power supply according to claim 7, wherein the fastener elements further comprise a plurality of positioning holes on the slotted wall and a plurality of positioning pins beneath the fan base; and each positioning pin plugs into a corresponding positioning hole.

10. The power supply according to claim 7, wherein the fastener elements further comprise a plurality hooks beneath the fan base; and the hooks run through the slotted wall's slots and engage the slotted wall.
